(19) United States
(12) Patent Application Publication
(10) Pub. No.: US 2003/0203544 A1
(43) Pub. Date: Oct. 30, 2003

(54) CMOS transistor on thin silicon-on-insulator using accumulation as conduction mechanism

(75) Inventor: Min-Hwa Chi, Hsinchu (TW)

Correspondence Address: Jan Carol Little, BLAKELY, SOKOLOFF, TAYLOR & ZAFMAN LLP, Seventh Floor, 12400 Wilshire Boulevard, Los Angeles, CA, 90025-1026, US

(73) Assignee: Worldwide Semiconductor Manufacturing Corporation

(21) Appl. No.: 10/414,678

(22) Filed: Apr. 15, 2003

Related U.S. Application Data
(62) Division of application No. 09/551,717, filed on Apr. 18, 2000.

(51) Int. Cl. H01L 21/00

(52) U.S. Cl. 438/149

(57) ABSTRACT

A transistor structure fabricated on a thin silicon-on-insulator layer. The transistor comprises: a body formed in a silicon layer of a first dopant type; a gate structure formed atop the body; a source adjacent a first edge of the gate structure formed of the first dopant type; and a drain adjacent a second edge of the gate structure formed of the first dopant type.

### CROSS-REFERENCE TO RELATED APPLICATIONS

This application is a divisional of, and claims priority from, U.S. patent application Ser. No. 09/551,717, filed Apr. 18, 2000, currently pending.

### FIELD OF THE INVENTION

The present invention relates to silicon-on-insulator (SOI) integrated circuits, and more particularly, to a CMOS transistor using accumulation as the conduction method.

### BACKGROUND OF THE INVENTION

Silicon-on-insulator (SOI) is gaining popularity as a new technology. Devices formed in SOI have demonstrated significant performance improvement over devices fabricated on bulk silicon wafers. This is because bulk silicon devices have problems with inherent parasitic to junction capacitance's. One way to avoid this problem is to fabricate the devices on an insulating substrate. Hence, SOI technology offers the highest performance in terms of power consumption and speed for a given feature size due to minimizing parasitic capacitance.

However, prior art CMOS transistors formed in SOI still suffer from various drawbacks, such as floating-body effect, kink effect, poor short channel effect, threshold voltage mismatch from bulk transistors, etc. . . . These problems are primarily related to having a floating body, which results from difficulties in making contacts to the body region with an opposite dopant type compared to the source and drain.

### BRIEF DESCRIPTION OF THE DRAWINGS

FIG. 1 is a cross-section view of a CMOS transistor formed in a silicon-on-insulator (SOI) substrate in accordance with the present invention.

FIGS. 2a and 2b illustrate an N-channel transistor formed in accordance with the present invention during an “off” and “on” state.

FIGS. 3a and 3b illustrate a P-channel transistor formed in accordance with the present invention during an “off” and “on” state.

FIG. 4 shows an inverter formed with an N-channel transistor and a P-channel transistor formed in accordance with the present invention.

FIG. 5 is a electrical representation of the inverter of FIG. 4.

### DETAILED DESCRIPTION OF THE PREFERRED EMBODIMENTS

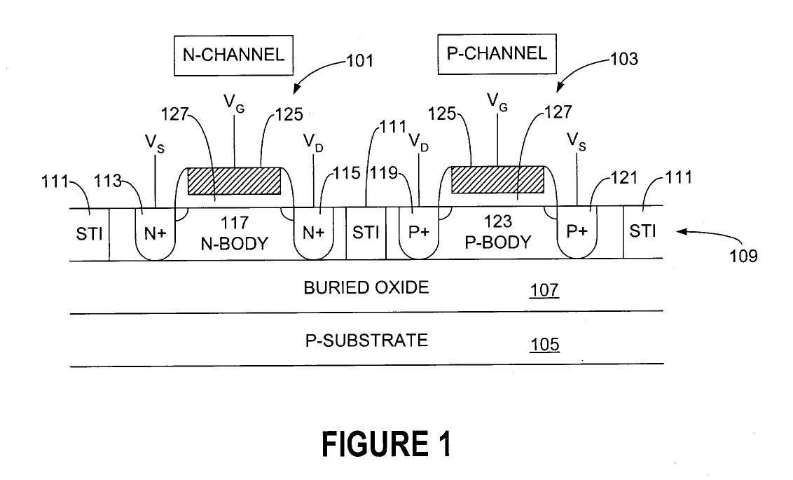

FIG. 1 shows an N-channel transistor 101 and a P-channel transistor 103, both formed in accordance with the present invention. The N-channel transistor 101 and the P-channel transistor 103 are both formed in a silicon-on-insulator (SOI) environment. The SOI is formed on a P-substrate 105. A buried oxide layer 107 forms the insulator part of the SOI. A thin silicon layer 109 is formed on top of the buried oxide 107. The thickness of the thin silicon layer 109 is about 0.1 micron. The details of forming a SOI environment is well known in the art and will not be discussed in further detail herein.

The N-channel transistor 101 and the P-channel transistor 103 are separated by shallow-trench-isolation (STI) structures 111 formed in the silicon layer 109. The STI structures 111 are formed using conventional techniques. A review of FIG. 1 reveals that the transistors 101 and 103 are similar to conventional CMOS transistors fabricated on bulk wafer silicon. The primary difference is that the body of the transistor is doped to be the same dopant type as the source and drain of the transistor.

For the N-channel transistor 101, the source 113 and the drain 115 are formed from N+ regions that both extend downwardly to the buried oxide layer 107. Additionally, the STI structures 111 also extend to the buried oxide 107. Next, an n-body region 117 between the source 113 and drain 115 is doped with n-type dopants. The body 117 is doped lightly enough so that it is completely depleted across the thin silicon layer. Further, the body 117 of the N-channel transistor 101, like the source 113 and drain 115, are completely isolated by the STI structures 111 and the buried oxide layer 107.

Similarly, the P-channel transistor 103 includes a source 119 and a drain 121 that are formed from P+ regions that preferably extend down to the buried oxide layer 107. Thus, the P-body 123 is completely isolated by the STI structures 111 and the buried oxide layer 107. Next, a p-body region 123 between the source 113 and drain 115 is doped with p-type dopants, and it is fully depleted across the thin silicon layer 109.

A conventional gate structure 125 is formed between the source and drains of the transistors 101 and 103. The gate 125 is separated from the silicon layer 109 by a gate oxide layer 127. Conventional lightly doped drain (LDD) regions may also be formed in the transistors.

In summary, the transistors 101 and 103 of the present invention are substantially similar to prior art CMOS transistors except that the body regions 117 and 123 are of the same dopant type as the source and drain of the associated transistors, and the body regions 117 and 123 are normally in full depletion.

In operation, when a zero voltage is applied to the gates 125, the underlying N-body 117 and P-body 123 are fully depleted and there is no current flowing between the source and drain of the transistors. Therefore, the transistor is off. When a bias voltage (positive V_{cc} for the n-channel transistor 101 and negative V_{cc} for the p-channel transistor 103) is applied to the gate 125, the body of the transistor is in accumulation mode and there is a large current between the source and drain.

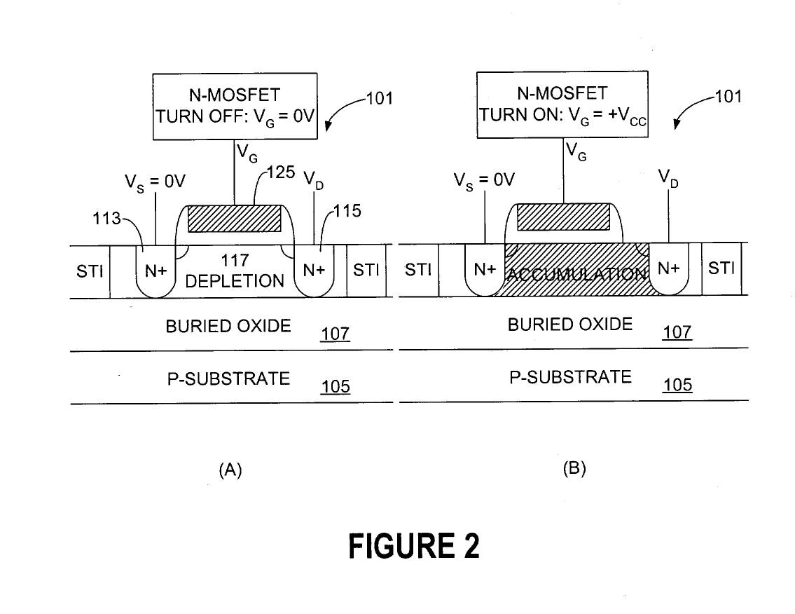

This can be seen in greater detail in FIGS. 2A and 2B for the n-channel transistor 101. When the gate 125 is at zero voltage in FIG. 2A, the entire N-body 117 is fully depleted. There is no current flowing between the source 113 and the drain 115. The dopant concentration of the N-body 117 must be low enough (e.g. same doping as in the body of a conventional p-channel transistor) so that a full depletion results when the gate 125 is at zero bias. When in depletion, the breakdown voltage across the N+ source 113 and the N+ drain 115 depends upon the length of the body 117 between the source and drain.

Turning to FIG. 2B, to turn on the transistor 101, the gate 125 is biased to V_{cc}. This results in the surface of the N-body 117 (directly under the gate oxide 127) to begin accumulation of electrons. Under these conditions, the drain 115 is now shorted to the source 113, and the entire N-body 117 will conduct current. The magnitude of voltage to be applied to the gate 125 for sufficient accumulation of electrons on the surface of the N-body 117 can be defined as the “threshold voltage” for accumulation (V_{th,acc}). Because the transistor 101 relies upon accumulation of electrons at the surface of the N-body 117, this type of transistor 101 is referred to as an “accumulation N-MOS transistor”.

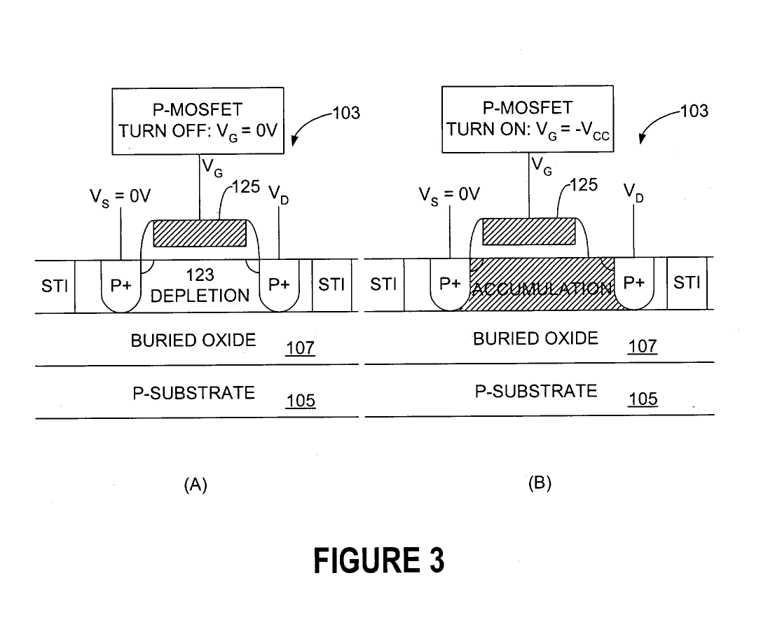

Turning to FIGS. 3A and 3B, an analysis for the P-channel transistor 103 is provided. For a P-channel transistor 103, the threshold voltage V_{th,acc} is defined as the voltage sufficient to induce accumulation of holes on the surface of the P-body 123. As seen in FIG. 3b, when a sufficient amount of holes accumulate in the P-body 123, this will turn on the transistor 103. When a zero voltage is applied to the gate 125, the body 123 is in depletion as shown if FIG. 3a. When a voltage of −V_{cc}, is applied to the gate 125, the P-body 123 is in accumulation mode. Typically, V_{cc} is 3.3 volts, but may be 1.8 volts or lower, depending on the thickness of the gate oxide used.

Some comments should be made with respect to the transistor design. The distance between the source and the drain of the transistors determines the total channel conductance during “on” state, as well as the drain blocking voltage during “off” state. The current-voltage characteristics of the transistors 101 and 103 exhibits similar behavior to conventional inversion MOSFETs. After turning on the transistor by applying a bias to the gate (V_{g}>V_{th,acc}), the drain current increases with the drain voltage until the accumulation begins to disappear near the drain side at V_{g}<V_{d}.

The threshold voltage V_{th,acc} for the transistors 101 and 103 can be adjusted by varying the gate oxide thickness, the work-function of the gate electrode 125 or the dopant concentration of the body 117 and 123. As a specific example for the N-channel transistor 101, N-type polysilicon doping of the gate 125 can result in a smaller V_{th,acc} (approximately 0 volts). A P-type polysilicon doping for the gate electrode 125 can result in a larger V_{th,acc} (approximately 1 volt). Further, if a metal material such as aluminum or tungsten is used as the gate electrode 125, the threshold voltage V_{th,acc} is near 0.5 volts. The threshold voltage V_{th,acc} can also be adjusted slightly by implanting dopants into the body 117 and by varying their concentration. Similar design considerations are applicable for a P-channel transistor 103.

The new transistors can be fabricated on thin SOI using CMOS compatible process steps, thus, both the new and conventional transistors can be fabricated together.

There are several advantages to the transistors 101 and 103 as described herein. First, the mobility of majority carriers is known to be larger than in a conventional inversion type transistor due to a lower field in the accumulation layers close to the surface of the bodies 117 and 123. Thus, the transistors 101 and 103 will have a larger driving capability then the corresponding inversion type transistors formed in bulk silicon wafers. Moreover, there is also a lower electrical field in the oxide during operation. Thus, higher oxide reliability of the new devices is expected. Thirdly, the noise level in the transistors 101 and 103 is much less than conventional transistors, since the current is mainly flowing in an accumulation layer. Thus, the new MOS transistors are more suitable for mixed-signal circuits.

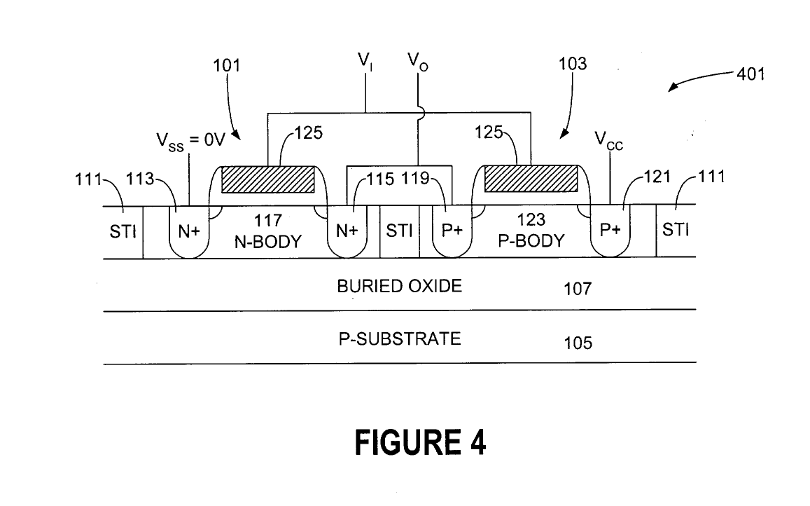

One application of the transistors 101 and 103 is shown in FIG. 4. In FIG. 4, an inverter 401 is illustrated. When the input V₁ to the gates 125 is low, the N-channel transistor 101 is off and the P-channel transistor 103 is on. Thus, the output V₀ is high. When the gate bias V₁ is high, then the P-channel transistor 103 is off and the N-channel transistor 101 is on. This results in the output voltage V₀ being low. Thus, an inverter can be formed using the transistors of the present invention.

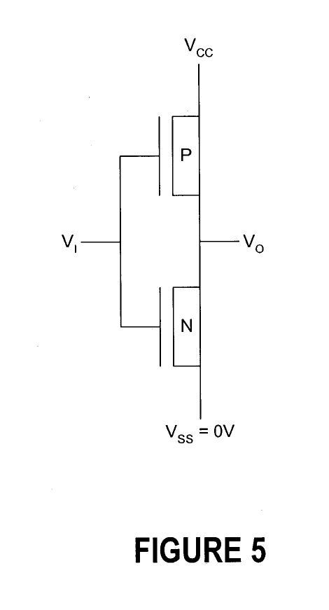

It is a simple design extension to form other logical building blocks such an NAND gates, NOR gates, etc. Thus, logic circuits that are typically formed using conventional inversion type transistors on bulk silicon wafers can also be easily fabricated on SOI environments based on the accumulation transistors of the present invention without changing circuit configuration or even layouts. FIG. 5 shows a electrical schematic diagram of the inverter of FIG. 4.

While the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A method of operating a P-channel transistor formed in a silicon-on-insulator (SOI) environment, the method comprising:
applying a first voltage to a gate structure formed atop a P-body formed in a semiconductor layer, the semiconductor layer formed on an insulator, the insulator formed on a semiconductor substrate, the first voltage to turn the P-channel transistor off by fully depleting the P-body;
applying second voltage to the gate structure to short a P+ source of the P-channel transistor to a P+ drain of the P-channel transistor by accumulating electrons at a surface of the P-body.

2. The method of claim 1 wherein applying a first voltage to the gate structure comprises applying a voltage that is more positive than a potential on the P+ drain to the gate structure.

3. The method of claim 1 wherein applying a second voltage to the gate structure comprises applying a voltage that is more negative than a potential on the P+ drain to the gate structure.

4. A method of operating a N-channel transistor formed in a silicon-on-insulator (SOI) environment, the method comprising:
applying a first voltage to a gate structure formed atop a N-body formed in a semiconductor layer, the semiconductor layer formed on an insulator, the insulator formed on a semiconductor substrate, to turn the N-channel transistor off by fully depleting the N-body;
applying second voltage to the gate structure to cause a surface of the N-body accumulate electrons and conduct current, and to short a N+ source of the N-channel transistor to a N+ drain of the N-channel transistor.

5. The method of claim 4 wherein applying a first voltage to the gate structure comprises applying a voltage that is more negative than a potential on the N+ drain to the gate structure.

6. The method of claim 4 wherein applying a second voltage to the gate structure comprises applying a voltage that is more positive than a potential on the N+ drain to the gate structure.

7. A method of operating an inverter having an N-N-N transistor coupled to a P-P-P transistor formed in a silicon-on-insulator (SOI) environment, wherein V_{CC} is connected to a P+ terminal of the P-P-P transistor, ground is connected to an N+ terminal of N-N-N transistor, and the gate on top of the N-N-N and P-P-P transistors are connected together, the method comprising:
turning an N-N-N transistor on by applying a first voltage to a common gate structure to accumulate electrons on an N-body surface of the N-N-N transistor; and
turning a P-P-P transistor off by applying the first voltage to a common gate structure to fully deplete electrons on P-body surface of the P-P-P transistor.

8. The method of claim 7, wherein turning an N-N-N transistor on by applying a first voltage to the common gate structure comprises turning an N-N-N transistor on by applying a voltage that is more positive than a potential on the N+ drain to the common gate structure.

9. The method of claim 7, further comprising:
turning the N-N-N transistor off by applying a second voltage to the common gate structure to deplete electrons on the N-body surface of the N-N-N transistor; and
turning the P-P-P transistor on by applying the second voltage to the common gate structure to accumulate electrons on the P-body surface of the P-P-P transistor.

10. The method of claim 9, wherein turning the P-P-P transistor on by applying the second voltage to the common gate structure comprises turning the P-P-P transistor on by applying a voltage that is more negative than a potential on the P+ drain to the common gate structure.

11. The method of claim 10, wherein turning the P-P-P transistor on by applying the second voltage to the common gate structure comprises turning the P-P-P transistor on by applying ground to the common gate structure.

12. The method of claim 7, wherein turning the N-N-N transistor on by applying the first voltage to the common gate structure comprises turning the N-N-N transistor on by applying V_{CC} to the common gate structure.
